(19) United States
(12) Patent Application Publication
(10) Pub. No.: US 2019/0018301 A1
(43) Pub. Date: Jan. 17, 2019

(54) Hexagonal Beryllium Borate Crystal

(71) Applicant: Clemson University, Clemson, SC (US)

(72) Inventors: Joseph William Kolis, Central, SC (US); Colin D. McMillen, Liberty, SC (US)

(21) Appl. No.: 15/648,801

(22) Filed: Jul. 13, 2017

(51) Int. Cl. G02F 1/355; C30B 29/10; C30B 7/10; G02F 1/37

(52) U.S. Cl. CPC G02F 1/3551; G02F 1/37; C30B 7/10; C30B 29/10

(57) ABSTRACT

Single, acentric, hexagonal, beryllium borate crystals having the formula Sr₂Be₂B₂O₇ with a new structural type with space group of P(-)6 and a unit cell of unit cell a=b=4.6709(7) Å, c=3.8410(7) Å and trigonal borate groups within the unit cell lattice whereby the trigonal groups are fully ordered and directly lined up above each other with no rotation of the stacking groups relative to each other. These crystals can be formed according to a hydrothermal formation process with a size sufficient for use in a variety of laser and nonlinear optical applications.

### STATEMENT REGARDING FEDERALLY SPONSORED RESEARCH OR DEVELOPMENT

This invention was made with government support under grant #1410727 awarded by The National Science Foundation. The government has certain rights in the invention.

### BACKGROUND

There is an increasing demand for lasers capable of generating coherent radiation in the lower half of the visible region (green→violet) and the ultraviolet region of the optical spectrum as coherent radiation at shorter wavelengths can have many useful properties. Shorter wavelength leads to greater resolution in applications such as lithography, micromachining, patterning, labeling, laser surgery, information storage and related applications. A convenient source of shorter wavelength (e.g., UV) radiation could lead to significant advances in spectroscopy, biological applications and sensor technology.

At present there are very few methods available for the generation of coherent radiation at wavelengths in the shorter wavelength ranges (e.g., from about 150 nm to about 400 nm). The most common techniques rely on excimer lasers based on gases like krypton fluoride or fluorine, capable of generating 193 nm and 157 nm laser radiation respectively. However, these lasers require the use of corrosive gases and they are large, bulky, unreliable and restricted to a few specific wavelengths. Diode lasers that emit in the UV below 355 nm are the subject of intense research and, although showing some promise, are plagued by short lifetimes, low power and generally limited performance.

Other approaches have attempted to utilize a relatively simple alternative for the generation of short wavelength laser radiation via multiple harmonic generation of readily available longer wavelength laser sources using non-linear optical frequency multiplying crystals according to a frequency doubling approach. Frequency doubling is a nonlinear optical process that combines two photons of one wavelength to produce a new photon of one half the wavelength. Thus it is energy neutral. The process is not notably efficient but requires only passive optical components. Crystals have been developed capable of use in a frequency doubling application (e.g., KTP, KTA, LiNbO₃ and KNbO₃), but they are not suitable for generation of shorter wavelength radiation.

There have been reports of single crystals with promising nonlinear optical properties with potential for use in development of shorter wavelength radiation generation having the formula Sr₂Be₂B₂O₇ (SBBO). U.S. Pat. No. 5,523,026 is directed to single crystals of that formula. According to the '026 patent, the SBBO crystals were grown out of molten fluxes of various formulations. Unfortunately, the growth method has not proven to be reproducible or suitable for crystals of sufficient quality for any optical application. Importantly, the single SBBO crystals formed according to the methods of the '028 patent do not have clearly defined internal symmetry operations.

Two different space groups have been reported for SBBO crystals P6(-)c2 (Chen et al Nature 1995, 373,322) and P6₃ (the '026 patent). In both reports the unit cell dimensions are given as a=b=4,663(3) Å, c=15.311(7) Å. These data are important because the space group and unit cell parameters and internal symmetry operations are essential to the accurate determination of the Sellmeier coefficients, phase matching curves, nonlinear coefficients and critical angles. Such factors are essential for proper cutting, aligning and design of nonlinear crystals in a practical solid-state UV laser device. Unfortunately, these known SBBO crystals also display considerable disorder of the planar borate groups that are responsible for the nonlinear optical properties of the crystals. In addition to creating the structural uncertainty that led to ambiguity about the space group of these SBBO crystals, the disorder of the borate groups reduces the nonlinear properties of the crystal. In a 2005 paper (Chen et al., Applied Physics B 2005, 80, 1), inventors of the '026 patent stated that despite many attempts using a number of diffraction methods including neutron diffraction, they were unable to resolve the structural ambiguities that exist in their SBBO crystals and had been unable to produce SBBO single crystals in a form that was unambiguously and repeatedly useful.

Alternative methods for forming SBBO crystals have been described including a hydrothermal method as described by Kolis et al, in U.S. Pat. No. 7,591,896, which is incorporated herein by reference. This method was described for use over a broad temperature range between about 350° C. and 600° C. using a variety of mineralizers.

What are needed in the art are crystals that can consistently and repeatedly generate coherent laser radiation in shorter wavelengths. More specifically, what are needed are SBBO crystals of sufficient quality with ordered structures and with nonlinear optical properties (e.g., wide bandgaps, high nonlinear coefficients, moderate birefringence) that can be useful in generating shorter wavelengths (e.g., about 550 nm or less) in optical applications.

### SUMMARY

According to one embodiment, disclosed is a hexagonal beryllium borate crystal having the formula Sr₂Be₂B₂O₇ (SBBO) having a space group of P(-)6 and a unit cell a=b=4.6709(7) Å, c =3.8410(7) Å.

Also disclosed are optical devices incorporating the SBBO crystals and hydrothermal methods for forming the SBBO crystals.

### BRIEF DESCRIPTION OF THE DRAWINGS

The accompanying drawings illustrate embodiments of the present invention and, together with the description given herein, serve to describe principles of the invention.

FIG. 1 presents the single crystal structure along the c-axis of an SBBO crystal as described herein.

FIG. 2 schematically compares the arrangement of the triangular borate groups along the c-axis in an SBBO crystal as described herein (left) with those of an SBBO crystal as previously reported (right).

FIG. 3 presents the single crystal structure along the b-axis of an SBBO crystal as described herein.

FIG. 4 schematically compares the arrangement of the triangular borate groups along the b-axis in an SBBO crystal as described herein (left) with those of an SBBO crystal as previously reported (right).

FIG. 5 schematically illustrates one embodiment of a hydrothermal growth system as may be utilized in forming an SBBO crystal.

### DETAILED DESCRIPTION

Reference will now be made in detail to various embodiments of the disclosed subject matter, one or more examples of which are set forth below. Each embodiment is provided by way of explanation of the subject matter, not limitation thereof. In fact, it will be apparent to those skilled in the art that various modifications and variations may be made in the present disclosure without departing from the scope or spirit of the subject matter, For instance, features illustrated or described as part of one embodiment, may be used in another embodiment to yield a still further embodiment.

The present disclosure is directed to a crystalline isomer of hexagonal strontium beryllium borate and to methods for forming the crystalline isomer as well as products incorporating the crystalline isomer. More specifically, disclosed are highly ordered Sr₂Be₂B₂O₇ (SBBO) crystals with consistent and useful nonlinear optical characteristics. In one embodiment, the SBBO crystals can be formed according to a hydrothermal crystal growth process, which can provide large single crystals of the disclosed structure as can be beneficially utilized in a variety of applications.

The disclosed SBBO crystals have a different crystal structure as compared to previously reported SBBO crystals. For instance, the disclosed crystals have a different space group and have a different unit cell from the previously known materials. In particular, the crystals can be formed in the acentric P(-)6 space group with a uniaxial acentric structure. In addition, the SBBO crystals can possess a wide band gap (e.g., about 200 nm or less) and can have a high nonlinear optical coefficient. As such, disclosed SBBO crystals can be employed in a number of applications including solid-state optoelectronic devices such as lasers that can emit coherent radiation in shorter wavelengths (e.g., less than about 550 nm, for instance between about 532 and about 210 nm wavelengths in some embodiments).

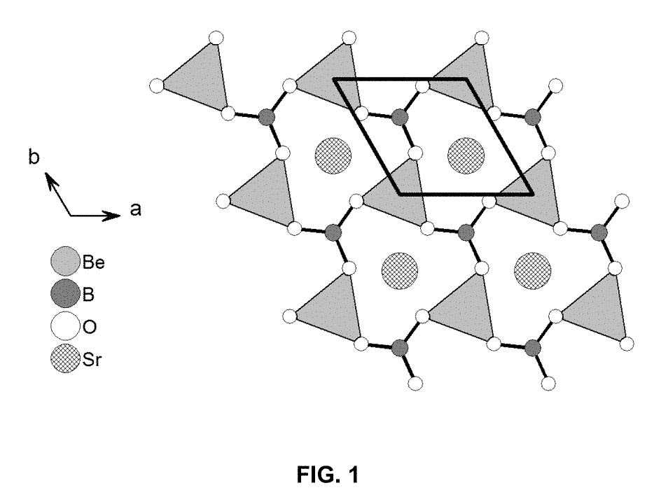

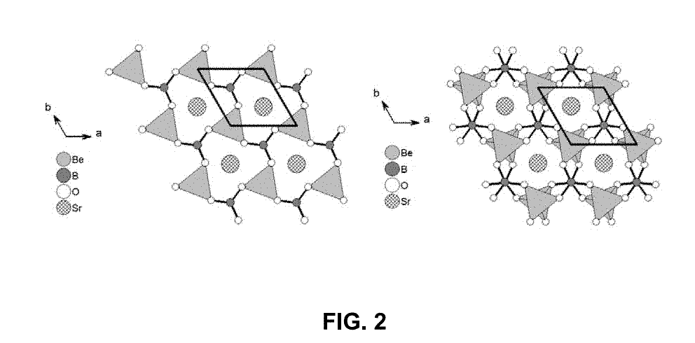

The crystal structure of the disclosed SBBO materials is the result of the planar borate groups being well ordered, all pointed in the same direction, and stacked in an ordered fashion directly upon one other as compared to previously known SBBO crystals (FIG. 1, FIG. 2). Without wishing to be bound to any particular theory, it is believed that the orderly stacking of the borate groups can allow for the borate groups to reinforce the ability of the crystal to perform nonlinear optical manipulation of photons. It is the trigonal borate groups that induce the nonlinear frequency conversion of a laser light and as such, the highly ordered arrangement of these groups in the disclosed crystals is believed to reinforce the degree of conversion.

Disordered borates as are found in previously known SBBO materials lead to ambiguities about the structural symmetry and space group and significantly decrease the nonlinear optical performance of the materials. Specifically, because the borate groups of previously known SBBO materials are arranged in partial opposition to one another they at least partially cancel out performance. Moreover, in previously described SBBO crystals the borates are rotated by a variety of angles relative to each other. These various rotations have not been fully characterized and this leads to an ambiguity in the actual space group. This is problematic because the correct symmetry of the crystals as defined by the space group is essential to the detailed physical and optical properties required for the correct critical angle and other vital parameters for effective frequency conversion in lasers. Additionally the rotated disordered borate groups cancel out the effect of nonlinear optical coefficients from each other, significantly decreasing the nonlinear frequency conversion in the laser. Such shortcomings have prevented the introduction of SBBO into devices and have even limited the determination of physical properties of the materials. In addition to such structural uncertainties, previously known SBBO products have been found to be too small, cracked, or flaky and generally of too poor quality for useful optical application.

The disclosed SBBO crystals can be formed in one embodiment according to a hydrothermal growth method as described further herein, which can provide the crystal structure with a very high consistency and can be used to form very large crystals. For instance, the crystals can be formed to a sufficient size and quality so as to be readily cut, polished and coated for a variety of optical applications.

The SBBO crystal described herein is in a P(-)6 space group with a unit cell of a=b=4.6709(7) Å, c=3.8410(7) Å. A top view of the unit cell of a crystal is displayed in FIG. 1. The space group is the designator that provides symmetry information and relationships within the crystalline lattice. This is important information because it is the overall symmetry of the crystal that determines optical properties such as “ordinary” and “extraordinary” optical axes, as well as the choice of faces and angles that perform the nonlinear optical operations in a product.

Disclosed crystals have a unit cell that is significantly different from that of the previously reported crystal with the same Sr₂Be₂B₂O₇ chemical formula. The unit cell of a crystal is important because it represents the fundamental building block of any crystalline lattice. The building block of the disclosed crystals represents an entirely different SBBO compound than those previously reported and discussed above. The unit cell parameters are important for the determination of the Sellmeier coefficients, critical angles and optical axes, which are essential to the proper alignment of a nonlinear crystal to perform nonlinear conversions.

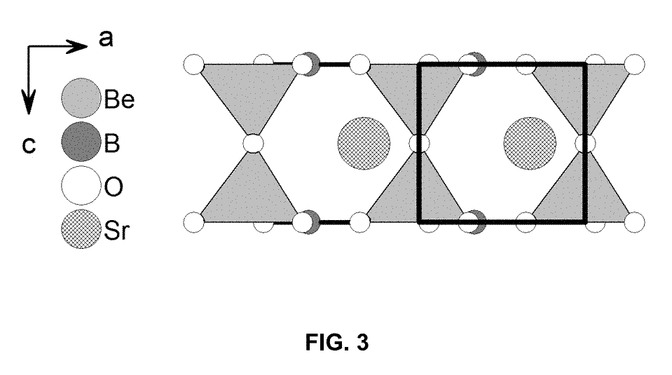

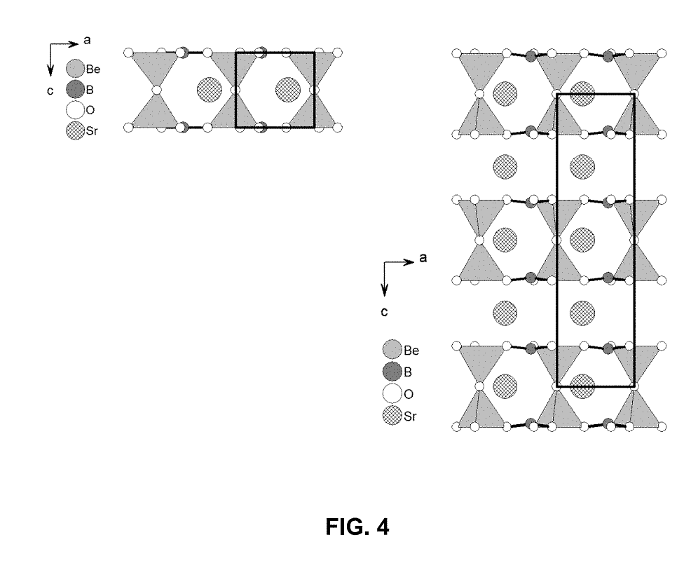

As can be seen in FIG. 1, FIG. 2, FIG. 3, and FIG. 4, the SBBO crystal has well-aligned trigonal borate groups, which provides for improved characteristics and in particular, improve non-linear characteristics, which can be highly beneficial in applications in UV solid-state lasers. The bandgap of the SBBO crystal can be similar to that of the previously disclosed SBBO materials, and the nonlinear optical coefficient can be higher than that of previously reported material. For example, the SBBO crystals can have a bandgap of about 200 nm or less and can have a nonlinear optical (NLO) coefficient, one of the key parameters in second harmonic generation of laser light, that is more about three times or more higher than that of β-BaB₂O₄ (BBO), which is the existing industry standard. For example, the NLO coefficient of an SBBO crystal as described herein can be up to about 4 pm/volt, for instance from about 3 pm/volt to about 4 pm/volt in some embodiments.

In the SBBO crystals described herein, the borates can be all arranged in the same direction, which can maximize their nonlinear efficiency. Furthermore, the well-ordered borate groups can ensure that the crystals have the described unit cell and space group and that the structure of the crystal can be unambiguous and reproducible. The reproducibility and consistency of the crystal can allow for workers skilled in the art to cut and polish the crystals at the correct critical angles to optimize phase matching, Fresnel scattering, walkoff parameters and other metrics necessary for efficient nonlinear behavior.

According to one embodiment, the disclosed crystals can be formed according to a hydrothermal growth method. This can provide for the formation of large crystals in one embodiment, for instance a monolithic crystal (i.e., a single crystal) having a dimension of at least 2 mm in at least one direction.

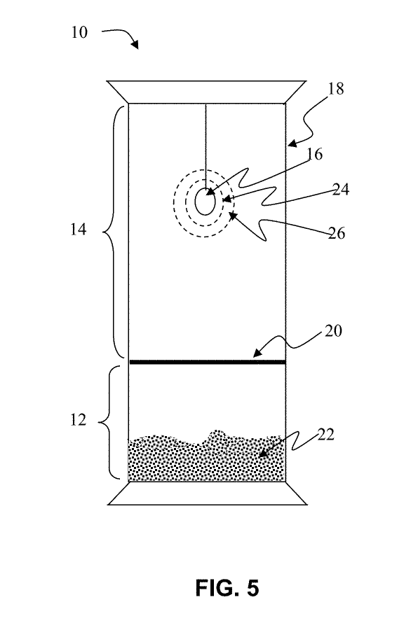

FIG. 5 illustrates one embodiment of a hydrothermal system 10 as may be utilized in forming an SBBO crystal. In general, a hydrothermal process involves the use of a superheated aqueous solution (liquid heated above its boiling point) under pressure (e.g., about 5 kpsi to about 30 kpsi) to cause transport of soluble species of a refractory oxide from a nutrient rich zone 12 to a supersaturated zone 14. As the refractory oxide is not sufficiently soluble in the superheated water, the species will crystallize, either spontaneously according to primary nucleation or alternatively on a seed crystal 16 located in the supersaturated zone 14.

A process can generally take place within a reactor 18. Depending on the chemical demands of the specific system, a reactor 18 can be lined with a noble metal such as silver, gold, platinum, palladium, etc. For instance, a liner can be a fixed liner or a floating liner. A fixed liner reactor can be in the form of a stand-alone autoclave that is lined with or formed of a desired material and can carry the reactants, products, etc. When utilizing a floating liner, a smaller structure that is lined with or formed of the desired material and containing the reactants can be held or suspended within a larger autoclave. For instance, an autoclave can contain a plurality of smaller tubes, e.g., silver tubes, each of which is loaded with reactants, water, seed crystals, etc. and each of which functions as a floating liner reactor within a larger autoclave. Materials for formation of a reactor are generally known in the art and include, without limitation, metals, quartz, ceramics, Teflon®, and so forth.

A reactor 18 is generally sealable, as with a cold seal, and can be of any desirable size depending, for example, on whether a process utilizes a fixed or floating liner, the size of product crystal to be formed by the process, energy requirements (e.g., temperatures and temperature gradient during a process), and so forth. For instance, a stand-alone autoclave reactor with either fixed liner or unlined can generally be between about 1 cm and about 10 cm in a cross sectional dimension and between about 10 cm and about 100 cm in height. A floating liner reactor can generally be smaller, for instance between about 0.25 cm and about 2 cm in diameter and between about 2.5 cm and about 10 cm in height. Of course, larger and smaller reactors are also encompassed herein.

A reactor 18 can include a baffle 20 between a nutrient rich zone 12 and a supersaturated zone 14. A baffle 20 can be formed of the same or different material as the wall of the reactor 18. For instance, when considering a silver lined or floating reactor 18, baffle 20 can also be silver or silver lined. Baffle 20 can define at least one aperture for passage of solution from the nutrient rich zone 12 to the supersaturated zone 14. A baffle 20 can aid in maintaining a temperature differential between the two zones and can encourage substantially isothermal characteristics in each zone. Baffle 20 can also restrict convective flow between nutrient rich zone 12 and supersaturated zone 14 and can channel the convective flow across the baffle 20 into a desirable geometry.

System 10 can also include heaters, insulators, controllers, etc, as are generally known in the art (not shown on FIG. 5). For instance, a system 10 can include an air space between insulation and the reactor wall. There can also be vents at strategic places to allow air flow to be controlled. Changing vent parameters and power delivered to heaters can determine the thermodynamic condition of the autoclave. Additionally, though illustrated in a vertical arrangement with the nutrient rich zone 12 below the supersaturated zone 14, this is not a requirement of the disclosed process, and the two zones can be located in any suitable location with regard to one another, for instance in a horizontal or any other angled relationship, as long as a temperature differential between the two can encourage convective flow there between.

According to one embodiment, a seed crystal 16 of SBBO having the structure as described herein can be placed in the supersaturated zone 14 to facilitate crystallization of a dissolved feedstock 22 from a supersaturated solution. Alternatively, no seed crystal be employed, and the formation method can utilize spontaneous growth of single crystals as described. Such spontaneously nucleated crystals typically grow on the side or top of the inert metal lining within the supersaturated zone 14 of the hydrothermal reactor 18.

Included in system 10 can be a feedstock 22 located in the nutrient rich zone 12 of reactor 18. The feedstock 22 can include microcrystalline powder suitable for the development of the Sr₂Be₂B₂O₇ crystalline material. In one embodiment the feedstock can include Sr₂Be₂B₂O₇ microcrystalline powder. In general, any Sr₂Be₂B₂O₇ microcrystalline powder can be utilized. Optionally the Sr₂Be₂B₂O₇ microcrystalline powder can be formed prior to placement in the reactor 18. For example, an Sr₂Be₂B₂O₇ microcrystalline powder may be formed by reacting a Sr²⁺ salt (e.g., Sr(CO₃), SrCl₂, SrO, etc. or combinations thereof), BeO, and a borate (e.g., H₃BO₃, B₂O₃ or a combination thereof) in an air atmosphere at a temperature of about 850° C. or higher for about 8 hours or more.

The feedstock 22 can be placed in the reactor 18 in conjunction with an aqueous solution. The aqueous solution used in the hydrothermal process can include a mineralizer that can facilitate dissolution and transport of the feedstock 18 from the nutrient rich zone 12 to the supersaturated zone 14. The identity and concentration of the mineralizer can be an important component of the hydrothermal growth method. Mineralizers are generally small molecules that can dissolve in the superheated fluid at the temperatures and pressures of a formation process and assist in dissolving and transporting the feedstock from a source to nucleation sites where crystal growth can occur.

In forming the SBBO crystals, the mineralizer can include one or both of alkali metal hydroxides CsOH and KOH at a combined concentration of from about 0.1 to about 1 molarity, for instance from about 0.25 M to about 1 M in some embodiments. The mineralizer can include CsOH and/or KOH in conjunction with one or more additional mineralizers including, without limitation, LiOH, NaOH, KOH, RbOH, or mixtures thereof, with the total alkali metal hydroxide concentration in the aqueous solution being from about 0.1 M to about 1 M, and the KOH and/or CsOH concentration being from about 0.25 M to about 1 M.

A mineralizer component can optionally include one or more additional small soluble salt generating anions and countercations in conjunction with the alkali metal hydroxide component. Additional anions can include but are not limited to carbonate or halides such as fluoride or chloride. The cations can include but are not limited to alkali ions such as Li⁺, Na⁺, K⁺, Cs⁺ or NH₄⁺.

During SBBO crystal formation, the superheated hydrothermal fluid can be contained in a reactor under pressure, typically between about 12 kpsi and about 15 kpsi. Growth and supersaturation control is achieved in a process by the use of a differential temperature gradient across a reactor. Referring again to FIG. 1, the nutrient rich zone 12 can be heated and feedstock 22 can dissolve in the hot hydrothermal fluid. The solution in the nutrient rich zone 12 becomes a saturated solution. The supersaturated zone 14 can be held at a slightly lower temperature. Consequently, the solution in the nutrient rich zone 12 can convect upward through the baffle 20 and into the supersaturated zone 14 where it will cool and become supersaturated. The dissolved feedstock can begin to come out of solution and build the SBBO crystal structure, either on a seed crystal 16 or spontaneously. The process can then continue until stopped or the feedstock supply is consumed.

Among the advantages of a hydrothermal crystal growth process are the relatively low operating temperatures. For instance, an SBBO growth process can generally be carried out with temperatures generally below about 600° C., for instance with temperatures within the reactor 18 ranging between about 530° C. and about 585° C., for instance from about 550° C. to about 580° C. This can simplify operating conditions and drastically minimize the amount of thermal strain regions of a forming crystal. The thermal gradient between the two zones 12, 14 of a reactor 18 can likewise vary according to specific materials and growth rates desired, but typically can be between about 20° C. and about 100° C. In particular, through control of the reaction conditions, including the presence of CsOH as a mineralizer within the described ranges and through tight control of the processing temperature in a hydrothermal process, the SBBO crystals thus formed can exhibit the unique crystal structure described herein.

The growth rate of a developing SBBO crystal can be between about 1 and about 5 microns per hour, or between about 30 and about 150 microns per day in cross sectional dimension. The relatively slow growth rates possible can be beneficial as this can allow for precise control of the thickness of the forming crystal. For example, a process can reliably grow a region at about 2 microns/hour or about 25 microns/day and can thus be used to grow a region of about 100 microns over four days.

Disclosed methods can be readily scaled to form more than one SBBO crystal simultaneously so time is not a hindering factor to a scale-up of a formation process. Moreover, once a process is started it can require no operator input over the course of the reaction and can be replicated reliably many times. As such, the total time of growth can be of little consequence in the overall production process. Moreover, a hydrothermal process can be utilized to form SBBO crystals of various shapes such as rods or disks, for instance depending upon the presence and shape of a seed crystal as well as the specific formation parameters. Typically formed crystals can be several hundred microns to several millimeters thick, though larger or smaller materials can be formed. Beneficially, a hydrothermal method can be utilized for production of disclosed SBBO crystals in sufficiently large size so as to be able to be cut and as such useful for optical and optoelectronic applications as well as other nonlinear optical applications. This size is typically in excess of about 3 mm to about 5 mm on any edge.

Use of a hydrothermal growth process can lead to production of large SBBO crystals of a size that is only limited by the size of the growth chamber and the time of growth. Thus, crystals up to several centimeters on an edge can be grown in some embodiments. In addition, the quality of the crystals can be very high and can be cut, polished and aligned to perform a wide variety of optoelectronic functions requiring acentric, birefringent crystals with an optical transparency near 150 nm, of a desired size. The SBBO crystals can be utilized for a wide variety of end-use applications related to uses in nonlinear optical solid-state lasers operating in the near ultraviolet and ultraviolet region.

By way of example, SBBO crystals as described herein can have a band edge of about 7 electron volts (approximately 170 nm) and can perform nonlinear optical activity. As such, the SBBO crystals can be useful in formation of laser systems, for instance solid state lasers configured to emit coherent light in shorter wavelengths, such as about 550 nm or less, for instance in the wavelength region between about 180 nm and 535 nm in some embodiments. For example, the crystals can exhibit nonlinear optical activity in a wavelength region between about 185 nm and about 532 nm.

The disclosure may be better understood with reference to the Example, set forth below.

### EXAMPLE 1

SBBO starting material was synthesized according to the solid-state reaction:

2SrCO₃+2BeO+2H₃BO₃→4Sr₂Be₂B₂O₇+2CO₂+3H₂O

The starting chemicals were weighed and ground to a homogeneous powder. This powder was placed in a platinum crucible and heated at 1000° C. for 18 h under air. The resulting white powder was used as the feedstock material for hydrothermal growth of SBBO crystals.

SBBO powder from the above reaction was placed in a silver ampoule whose bottom had been welded shut (for ¼″ ampoules, 0.1 g SBBO starting material and 0.4 mL of 0.25 M CsOH mineralizer were used; for ⅜″ ampoules, 1 g SBBO starting material and 4 mL mineralizer were used). After the mineralizer solution was added to the ampoule, the top of the ampoule was crimped and welded shut.

The ampoules were placed in an autoclave and counter pressured with water to prevent the ampoules from bursting (approximately 15 kpsi pressure). The autoclave was sealed and heated (either in a vertical furnace or by ceramic band heaters) to about 580° C. at the bottom nutrient rich zone and about 550° C. at the top supersaturated zone, and held at temperature for five days. The yields of these reactions were 100% SBBO single crystals in the structure of the unit cell and space group as described herein. The crystal contained fully ordered borate groups.

### EXAMPLE 2

SBBO crystals formed as described in Example 1 having space group P(-)6 and a unit cell of a=b=4.6709(7) Å, c=3.8410(7) Å, with no disordered borate groups, of approximate dimension 1-3 mm per edge had small holes drilled though them and were tied using 0.1 mm diameter platinum wire onto a platinum ladder fashioned from 1 mm diameter wire. The crystals were then placed within the confines of a reactor such that the crystals were 5-6 inches above the level of the SBBO feedstock prepared as described above and a small baffle was placed slightly above the highest level of the feedstock.

Using 0.25 M aqueous CsOH as hydrothermal fluid, a thermal gradient with 580° C. nutrient enriched zone and a 550° C. supersaturated zone was established within the reactor and held for six days. Over this course of time, over 200 mg of SBBO feedstock was transported and a very high quality single crystal was grown. The crystal had a space group P(-)6 and unit cell of a=b=4.6709(7) Å, c=3.8410(7) Å, and contained ordered borate groups. The dimension of the seed increased by several millimeters on each edge over this time period. Once the equilibrium was reached the transport rates were approximately constants, growth of the single crystal continued as long as the feedstock was present and the thermal gradient was maintained,

Embodiments of the subject matter have been described using specific terms and devices. The words and terms used are for illustrative purposes only, The words and terms are words and terms of description, rather than of limitation. It is to be understood that changes and variations may be made by those of ordinary skill art without departing from the spirit or scope of the invention, which is set forth in the following claims. In addition it should be understood that aspects of the various embodiments may be interchanged in whole or in part. Therefore, the spirit and scope of the appended claims should not be limited to descriptions and examples herein.

What is claimed is:

1. A hexagonal beryllium borate crystal having the formula Sr₂Be₂B₂O₇ (SBBO), with a space group of P(-)6 and a unit cell of a=b=4.6709(7) Å, c=3,8410(7) Å and trigonal borate groups (BO₃) within the unit cell lattice.

2. The hexagonal beryllium borate crystal of claim 1, wherein the trigonal borate groups are stacked directly over one another in the unit cell.

3. The hexagonal beryllium borate crystal of claim 1, wherein the crystal has a band edge of about 7 electron volts.

4. The hexagonal beryllium borate crystal of claim 1, wherein the crystal exhibits nonlinear optical activity in a wavelength region between about 185 nm and about 532 nm.

5. The hexagonal beryllium borate crystal of claim 1, wherein the crystal is about 3 millimeters or larger along an edge.

6. The hexagonal beryllium borate crystal of claim 1, wherein the crystal is a cut and polished crystal.

7. A laser incorporating a hexagonal beryllium borate crystal having the formula Sr₂Be₂B₂O₇ (SBBO), with a space group of P(-)6 and a unit cell of a=b=4.6709(7) Å, c=3.8410(7) Å and trigonal borate groups (BO₃) within the unit cell lattice.

8. The laser of claim 7, wherein the laser is a solid state laser.

9. The laser of claim 7, wherein the laser emits coherent light at a wavelength of about 550 nm or less.

10. The laser of claim 7, wherein the laser emits coherent light at a wavelength between about 185 nm and about 532 nm.

11. A method for forming a hexagonal beryllium borate crystal comprising:
locating a feedstock within a nutrient rich zone of a reactor, the feedstock comprising a sources for forming a Sr₂Be₂B₂O₇ crystal;
locating an aqueous solution in the nutrient rich zone of the reactor, the aqueous solution comprising a mineralizer including at least one of cesium hydroxide and potassium hydroxide, wherein the cesium hydroxide and/or potassium hydroxide is present in the aqueous solution in an amount of from about 0.1 M to about 1 M;
heating the nutrient rich zone of the reactor to a temperature of from about 530° C. to about 580° C. at a pressure of from about 12,000 psi to about 15,000 psi;
maintaining a supersaturation zone of the reactor in fluid communication with the nutrient rich zone, the supersaturation zone being maintained at a temperature that is from about 20° C. to about 100° C. lower than the temperature of the nutrient rich zone; wherein
a hexagonal beryllium borate crystal is thereafter grown in the supersaturation zone, the hexagonal beryllium borate crystal having the formula Sr₂Be₂B₂O₇ (SBBO), with a space group of P(-)6 and a unit cell of a=b=4.6709(7) Å, c=3,8410(7) Å and trigonal borate groups (BO₃) within the unit cell lattice.

12. The method of claim 11, wherein the feedstock comprises Sr₂Be₂B₂O₇ microcrystalline powder.

13. The method of claim 12, further comprising forming the Sr₂Be₂B₂O₇ microcrystalline powder.

14. The method of claim 13, wherein the Sr₂Be₂B₂O₇ microcrystalline powder is formed by reaction of a Sr²⁺ salt, BeO, and a borate.

15. The method of claim 11, the mineralizer comprising cesium hydroxide.

16. The method of claim 15, the mineralizer comprising cesium hydroxide in an amount of from about 0.1 M to about 1 M.
